(19) United States
(12) Patent Application Publication
(10) Pub. No.: US 2024/0387603 A1
(43) Pub. Date: Nov. 21, 2024

(54) LIGHT EMITTING DEVICE AND DISPLAY DEVICE HAVING THE SAME

(71) Applicant: LG Display Co., Ltd., Seoul (KR)

(72) Inventor: YoungHo JEON, Paju-si (KR)

(73) Assignee: LG Display Co., Ltd., Seoul (KR)

(21) Appl. No.: 18/656,109

(22) Filed: May 6, 2024

(30) Foreign Application Priority Data
May 17, 2023 (KR) 10-2023-0063856

(51) Int. Cl. H01L 27/15; H01L 33/00; H01L 33/42; H01L 33/44

(52) U.S. Cl. CPC H01L 27/156; H01L 33/0095; H01L 33/42; H01L 33/44

(57) ABSTRACT

A light-emitting element according to an example of the present disclosure includes a first type semiconductor layer, a passivation layer disposed to cover a side surface and an edge of an upper surface of the first type semiconductor layer, an active layer disposed above the first type semiconductor layer and the passivation layer, a second type semiconductor layer disposed above the active layer, and an electrode. The electrode is disposed to cover a side surface of the passivation layer, a side surface of the active layer, a side surface of the second type semiconductor layer, and an upper surface of the second type semiconductor layer.

### CROSS-REFERENCE TO RELATED APPLICATIONS

This application claims priority to Korean Patent Application No. 10-2023-0063856 filed on May 17, 2023, in the Korean Intellectual Property Office, the entire contents of which are hereby expressly incorporated by reference into the present application.

### BACKGROUND

### Field

The present disclosure relates to a light-emitting element (also referred to herein as a light-emitting device) and a display device including the same, and more particularly, to a light-emitting element, which is easy to electrically connect and repair, and to a display device including the same.

### Discussion of the Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

Among the various display devices, a light-emitting display device refers to a display device that autonomously emits light. Unlike a liquid crystal display device, the light-emitting display device does not require a separate light source and thus can be manufactured as a lightweight, thin display device.

In addition, the light-emitting display device is advantageous in terms of power consumption because the light-emitting display device operates at a low voltage. Further, the light-emitting display device is expected to be adopted in various fields because the light-emitting display device is also excellent in implementation of colors, response speeds, viewing angles, and contrast ratios (CRs).

### SUMMARY OF THE DISCLOSURE

An object to be achieved by one or more embodiments of the present disclosure is to provide a light-emitting element that is easy to connect electrically.

Another object to be achieved by one or more embodiments of the present disclosure is to provide a display device that is easy to repair for a defect.

Still another object to be achieved by one or more embodiments of the present disclosure is to provide a display device capable of implementing high resolution.

Another object of the present disclosure is to provide a light-emitting device and a display device, which can address the limitations and disadvantages associated with the related art.

Objects of the present disclosure are not limited to the above-mentioned objects, and other objects, which are not mentioned above, can be clearly understood by those skilled in the art from the following descriptions.

A light-emitting element according to an embodiment of the present disclosure can include a p-type layer, a passivation layer disposed to cover a side surface and an edge of an upper surface of the p-type layer, an active layer disposed above the p-type layer and the passivation layer, an n-type layer disposed above the active layer, and an n-type electrode disposed to cover a side surface of the passivation layer, a side surface of the active layer, a side surface of the n-type layer, and an upper surface of the n-type layer.

A display device according to another embodiment of the present disclosure can include a substrate on which a plurality of pixels including a plurality of subpixels are defined, a plurality of transistors respectively disposed above the plurality of subpixels, a first planarization layer disposed above the plurality of transistors, a first connection electrode disposed above the first planarization layer and connected to the plurality of transistors, a second connection electrode disposed above the first planarization layer and spaced apart from the first connection electrode, and a light-emitting element disposed above the first connection electrode and the second connection electrode and electrically connected to the first connection electrode and the second connection electrode. Here, the light-emitting element includes a p-type semiconductor layer, a passivation layer disposed to cover a side surface and an edge of an upper surface of the p-type semiconductor layer, an active layer disposed above the p-type semiconductor layer and the passivation layer, a n-type semiconductor layer disposed above the active layer, and an n-type electrode disposed to cover a side surface of the passivation layer, a side surface of the active layer, a side surface of the n-type semiconductor layer, and an upper surface of the n-type semiconductor layer.

Other detailed matters of the exemplary embodiments are included in the detailed description and the drawings.

According to one or more embodiments of the present disclosure, the light-emitting element can be easily connected electrically by physical contact.

According to one or more embodiments of the present disclosure, a defective light-emitting element can be easily removed, which can make it easy to repair a defect of the display device.

According to one or more embodiments of the present disclosure, a vertical type light-emitting element, which has a relatively larger light-emitting area than a horizontal type light-emitting element, can be disposed, which can implement the high-resolution display device.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view of a light-emitting element according to an embodiment of the present disclosure;

FIG. 2 is a schematic view of a display device according to an embodiment of the present disclosure;

FIG. 3A is a schematic enlarged top plan view of one pixel of the display device according to the embodiment of the present disclosure;

FIG. 3B is a cross-sectional view taken along line A-A′ in FIG. 3A;

FIG. 4A is a schematic enlarged top plan view of one pixel of a display device according to another embodiment of the present disclosure;

FIG. 4B is a cross-sectional view taken along line B-B′ in FIG. 4A;

FIG. 5 is a cross-sectional view of a display device according to still another embodiment of the present disclosure; and

FIGS. 6A to 6C are structure diagrams for illustrating a process of repairing a defective pixel of the display device according to the embodiment of the present disclosure.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the disclosure. Further, in the following description of the present disclosure, a detailed explanation of known related technologies can be omitted or may be provided briefly to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings. All the components of each light-emitting device and each display device according to all embodiments of the present disclosure are operatively coupled and configured.

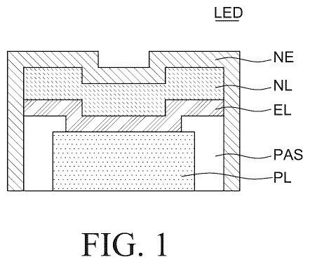

FIG. 1 is a cross-sectional view of a light-emitting element (also referred to herein as a light-emitting device) according to an embodiment of the present disclosure.

With reference to FIG. 1, a light-emitting element LED according to an embodiment of the present disclosure can include a p-type layer PL, an active layer EL, an n-type layer NL, an n-type electrode NE, and a passivation layer PAS. The light-emitting element can be a light-emitting diode or other type of light-emitting device.

The p-type layer PL is a layer for injecting positive holes into the active layer EL. For example, the p-type layer PL can be formed by doping a gallium nitride (GaN) semiconductor layer, which is formed by growing a gallium nitride (GaN) layer, with p-type impurities such as magnesium (Mg), zinc (Zn), and beryllium (Be). However, the present disclosure is not limited thereto. The p-type layer PL can be a first type semiconductor layer.

The passivation layer PAS can be disposed on the p-type layer. The passivation layer PAS can be disposed to cover a side surface of the p-type layer PL and an edge of an upper surface of the p-type layer PL extending from the side surface of the p-type layer PL. The passivation layer PAS can be disposed to expose a part of the upper surface of the p-type layer PL.

The passivation layer PAS can be made of an insulating material. For example, the passivation layer PAS can be configured as an inorganic layer made of silicon nitride (SiNx), silicon oxide (SiOx), and silicon oxynitride (SiON). However, the present disclosure is not limited thereto.

The active layer EL can be disposed on the p-type layer PL and the passivation layer PAS. For example, the active layer EL can be disposed to contact the passivation layer PAS and a part of the upper surface of the p-type layer PL exposed from the passivation layer PAS. Therefore, the active layer EL can be electrically connected to the p-type layer PL.

The active layer EL is a layer that emits light by combining electrons and positive holes. For example, the active layer EL can be a multi-quantum well structure in which a plurality of barrier layers and a plurality of well layers are alternately disposed, the well layer is configured as an indium gallium nitride (InGaN) layer, and the barrier layer is made of gallium nitride (GaN). However, the present disclosure is not limited thereto.

The n-type layer NL can be disposed on the active layer EL. The n-type layer NL is a layer for supplying electrons to the active layer EL. For example, the n-type layer NL can be formed by doping a gallium nitride (GaN) semiconductor layer, which is formed by growing a gallium nitride (GaN) layer, with n-type impurities such as silicon (Si). However, the present disclosure is not limited thereto. The n-type layer NL can be a second type semiconductor layer.

An n-type electrode NE can be disposed on the n-type layer NL. The n-type electrode NE can be disposed on an outermost layer disposed on a side surface of the light-emitting element LED and an upper surface of the light-emitting element LED. For example, the n-type electrode NE can be disposed to cover a side surface of the passivation layer PAS, a side surface of the active layer EL, a side surface of the n-type layer NL, and an upper surface of the n-type layer NL. For example, the n-type electrode NE can be disposed to have a structure that caps an outer surface of the light-emitting element LED.

The n-type electrode NE is a layer disposed to inject electrons into the active layer EL through the n-type layer NL. The n-type electrode NE can be made of an electrically conductive material having transparency so that the n-type electrode NE can transmit light upward, which is emitted from the active layer EL. For example, the n-type electrode NE can be a transparent electrode. For example, the n-type electrode NE can be made of transparent conducting oxide or made of indium tin oxide (ITO) or indium zinc oxide (IZO). However, the present disclosure is not limited thereto.

With reference to FIG. 1, a lower end of the n-type electrode NE and a lower end of the p-type layer PL can be disposed on the same plane. Therefore, the n-type electrode NE and the p-type layer PL can be respectively disposed on a second connection electrode and a first connection electrode of the display device, which will be described below, and electrically connected to the second connection electrode and the first connection electrode. In this case, the passivation layer PAS can be disposed between the n-type electrode NE and the p-type layer PL and insulate the n-type electrode NE and the p-type layer PL.

Meanwhile, because the lower end of the n-type electrode NE and the lower end of the p-type layer PL are disposed on the same plane in the light-emitting element LED according to the embodiment of the present disclosure, the first and second connection electrodes of the display device can be disposed below the light-emitting element LED and electrically connected to the light-emitting element LED. Therefore, the lower portion of the light-emitting element LED can be electrically connected to the electrodes of the display device, and at the same time, the light-emitting element LED can constitute a vertical type light-emitting element.

The light-emitting element LED according to the embodiment of the present disclosure is disposed to have the structure in which the n-type electrode NE caps the outer surface of the light-emitting element LED, which can improve coupling properties with the electrode of the display device.

For example, the n-type electrode NE is disposed on the outermost layer disposed not only on the bottom surface of the light-emitting element LED but also on the side surface of the light-emitting element LED and the upper surface of the light-emitting element LED, such that the n-type electrode NE can be disposed to have the structure that caps the outer surface of the light-emitting element LED. Therefore, the light-emitting element LED can be electrically connected to the electrode of the display device only by physical contact with the electrode of the display device without a separate component such as a line to be electrically connected to the electrode of the display device. As such, the light-emitting element LED can be easily connected to the electrode of the display device. Accordingly, because the light-emitting element LED according to the embodiment of the present disclosure can be electrically connected to the electrode of the display device by physical contact with the electrode of the display device, the light-emitting element LED can be easily connected to the electrode of the display device, and the coupling properties with the electrode of the display device can be improved.

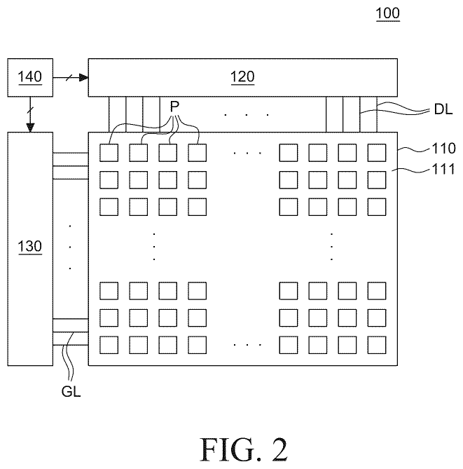

Hereinafter, a display device 100 according to an embodiment of the present disclosure, to which the light-emitting element LED according to the embodiment of the present disclosure is applied, will be described with reference to FIG. 2.

Particularly, FIG. 2 is a schematic view of the display device according to the embodiment of the present disclosure.

For convenience of description, FIG. 2 illustrates a display panel 110, a data drive part (or a data driver) 120, a gate drive part (or a gate driver) 130, a timing controller 140, a plurality of pixels P, a plurality of data lines DL, and a plurality of gate lines GL among various constituent elements of the display device 100.

With reference to FIG. 2, the display device 100 according to the embodiment of the present disclosure can include the display panel 110, the data drive part 120, the gate drive part 130, and the timing controller 140.

The display panel 110 is a panel configured to display images. The display panel 110 can include various circuits, various lines, and the light-emitting elements LED disposed on a substrate 111. The plurality of data lines DL and the plurality of gate lines GL, which intersect one another, can be disposed on the substrate 111 of the display panel 110, and the plurality of pixels P connected to the plurality of data lines DL and the plurality of gate lines GL can be defined.

The display panel 110 can include a display area defined by the plurality of pixels P, and a non-display area in which various types of signal lines or various pads are formed. The display panel 110 can be implemented as the display panel 110 used for various light-emitting display devices such as a liquid crystal display device, a light-emitting display device using organic light-emitting elements or LEDs, or an electrophoresis display device. Hereinafter, the configuration will be described in which the display panel 110 is a panel used for a light-emitting display device. However, the present disclosure is not limited thereto.

The timing controller 140 can receive timing signals such as a vertical synchronizing signal, a horizontal synchronizing signal, a data enable signal, and a dot clock signal through a receiving circuit such as an LVDS or TMDS interface connected to a host system. Based on the inputted timing signal, the timing controller 140 can generate timing control signals for controlling the data drive part 120 and the gate drive part 130.

The data drive part 120 can be connected to the plurality of data lines DL of the display panel 110 and supply data voltages to the plurality of pixels P. The data drive part 120 can include a plurality of source drive integrated circuits (ICs). The plurality of source drive ICs can receive digital video data and source timing control signals from the timing controller 140. The plurality of source drive ICs can generate the data voltage by converting the digital video data into gamma voltages in response to the source timing control signal and supply the data voltage through the plurality of data lines DL of the display panel 110.

The plurality of source drive ICs can be connected to the plurality of data lines DL of the display panel 110 by a chip-on-glass (COG) process, a chip-on-film (COF) process, or a tape automated bonding (TAB) process. In addition, the plurality of source drive ICs can be formed on the display panel 110 or a separate printed circuit board (PCB) substrate and connected to the display panel 110. The embodiments of the present disclosure are not limited thereto.

The gate drive part 130 is connected to the plurality of gate lines GL of the display panel 110 and supplies gate signals to the plurality of pixels P. The gate drive part 130 can include a level shifter and a shift register. The level shifter can shift a level of a clock signal inputted at a transistor-transistor-logic (TTL) level from the timing controller 140 and supply the clock signal to the shift register. The shift register can be formed by a gate-in-panel (GIP) method in the non-display area of the display panel 110. However, the present disclosure is not limited thereto. The shift register can include a plurality of stages configured to shift the gate signal to correspond to the clock signal and the driving signal and output the gate signal. The plurality of stages included in the shift register can sequentially output the gate signals through a plurality of output terminals.

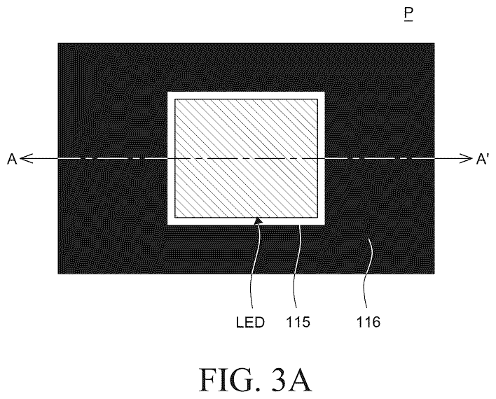

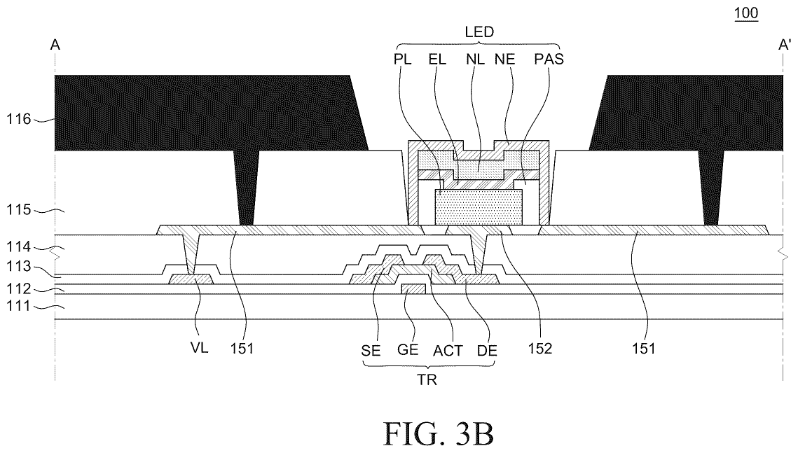

Hereinafter, one pixel P of the display device 100 according to the embodiment of the present disclosure will be described with reference to FIGS. 3A and 3B. Each pixel of the display device 100 can have the configuration shown in FIGS. 3A and 3B.

FIG. 3A is a schematic enlarged top plan view of one pixel of the display device according to the embodiment of the present disclosure.

FIG. 3B is a cross-sectional view taken along line A-A′ in FIG. 3A.

For convenience of description, FIG. 3A illustrates a second planarization layer 115, a bank 116, and the light-emitting element LED among various constituent elements of the display device.

With reference to FIGS. 2 and 3A together, the plurality of pixels P can be defined on the substrate 111. The plurality of pixels P can each include a plurality of subpixels. FIG. 3A illustrates that only one light-emitting element LED is disposed on one pixel P. However, a plurality of light-emitting elements LED can be disposed on one pixel P. The present disclosure is not limited thereto.

For example, one pixel P can include a plurality of subpixels SP, e.g., a red subpixel configured to emit red light, a green subpixel configured to emit green light, and a blue subpixel configured to emit blue light and further include a white subpixel configured to emit white light. The present disclosure is not limited thereto.

With reference to FIGS. 3A and 3B together, the display device 100 according to the embodiment of the present disclosure can include the substrate 111, a gate insulation layer 112, a transistor TR, a power line VL, an insulation layer 113, a first planarization layer 114, a first connection electrode 152, a second connection electrode 151, the second planarization layer 115, the light-emitting element LED, and the bank 116.

With reference to FIG. 3B, the substrate 111 can be disposed at the bottom of the display device 100.

The substrate 111 can support and protect constituent elements of the display device 100. The substrate 111 can be made of a transparent material such as glass. However, the present disclosure is not limited thereto.

A plurality of transistors TR can be respectively disposed on the plurality of subpixels on the substrate 111. For example, the transistor TR can include a gate electrode GE, an active layer ACT, a source electrode SE, and a drain electrode DE. For example, the transistor TR can be used as a driving element of the display device 100.

In the display device 100 according to the embodiment of the present disclosure, the transistor with a bottom gate structure is illustrated in which the gate electrode GE of the transistor TR is disposed at a lowermost side, the active layer ACT is disposed on the gate electrode GE, and the source electrode SE and the drain electrode DE are disposed on the active layer ACT. However, the present disclosure is not limited thereto.

The gate electrode GE of the transistor TR can be disposed on the substrate 111. The gate electrode GE can be made of any one of various metallic materials, for example, tantalum (Ta), molybdenum (Mo), aluminum (Al), chromium (Cr), gold (Au), titanium (Ti), nickel (Ni), neodymium (Nd), copper (Cu), and an alloy of two or more of these materials or configured as a multilayer made of any one of these materials. However, the present disclosure is not limited thereto.

The gate insulation layer 112 can be disposed on the gate electrode GE of the transistor TR. The gate insulation layer 112 can be a layer for electrically insulating the gate electrode GE and the active layer ACT and made of an insulating material. For example, the gate insulation layer 112 can be configured as a single layer made of silicon nitride (SiNx) or silicon oxide (SiOx) that is an inorganic material. Alternatively, the gate insulation layer 112 can be configured as a multilayer made of silicon nitride (SiNx) or silicon oxide (SiOx). However, the present disclosure is not limited thereto.

The active layer ACT can be disposed on the gate insulation layer 112.

The active layer ACT can be disposed to overlap the gate electrode GE. For example, the active layer ACT can be made of an oxide semiconductor or made of an amorphous semiconductor, such as amorphous silicon, polycrystalline silicon (poly-Si), an organic semiconductor, or the like. However, the present disclosure is not limited thereto.

The source electrode SE and the drain electrode DE can be disposed on the active layer ACT. The source electrode SE and the drain electrode DE can be disposed on the same layer and spaced apart from each other. The source electrode SE and the drain electrode DE can be electrically connected to the active layer ACT while contacting the active layer ACT.

The source electrode SE and the drain electrode DE can each be made of any one of various metallic materials, for example, tantalum (Ta), molybdenum (Mo), aluminum (Al), chromium (Cr), gold (Au), titanium (Ti), nickel (Ni), neodymium (Nd), copper (Cu), and an alloy of two or more of these materials or configured as a multilayer made of any one of these materials. However, the present disclosure is not limited thereto.

The power line VL can be disposed adjacent to the transistor TR. Specifically, the power line VL can be disposed on the gate insulation layer 112. The power line VL can be disposed on the same layer as the source electrode SE and the drain electrode DE and spaced apart from the source electrode SE and the drain electrode DE. The power line VL can be made of the same material as the source electrode SE and the drain electrode DE or made of the same material as the gate electrode GE. However, the present disclosure is not limited thereto.

For example, the power line VL can be a low-potential power line. In this case, a low-potential voltage can be supplied to the power line VL. However, the present disclosure is not limited thereto. The power line VL can be a high-potential power line. The power line VL is connected to the second connection electrode to be described below. The power line VL can be connected to the n-type electrode NE of the light-emitting element LED through the second connection electrode. Therefore, the power line VL can transmit the low-potential voltage to the second connection electrode and the n-type electrode NE of the light-emitting element LED.

The insulation layer 113 can be disposed on the transistor TR and the power line VL. The insulation layer 113 can be disposed above the transistor TR and the power line VL and protect the transistor TR and the power line VL. The insulation layer 113 can be an inorganic insulation layer. For example, the insulation layer 113 can be configured as a single layer made of silicon nitride (SiNx) or silicon oxide (SiOx) that is an inorganic material. Alternatively, the insulation layer 113 can be configured as a multilayer made of silicon nitride (SiNx) or silicon oxide (SiOx). However, the present disclosure is not limited thereto.

The first planarization layer 114 can be disposed on the plurality of transistors TR and the insulation layer 113. An upper surface of the first planarization layer 114 is a surface parallel to the substrate 111. The first planarization layer 114 can eliminate a level difference that can occur because of constituent elements, such as the transistor and the line, disposed below the first planarization layer 114. Therefore, the first planarization layer 114 can be an organic insulation layer. For example, the first planarization layer 114 can be made of any one of photo acrylic resin, acrylic resin, epoxy resin, phenolic resin, polyamide-based resin, polyimide-based resin, unsaturated polyester-based resin, polyphenylene-based resin, polyphenylene sulfide-based resin, benzocyclobutene, and photoresist. However, the present disclosure is not limited thereto. The first planarization layer 114 can be configured as a multilayer structure such as an inorganic layer/organic layer structure, an inorganic layer/organic layer/inorganic layer structure, or the like.

The first connection electrode 152 and the second connection electrode 151 can be disposed on the first planarization layer 114.

For example, the first connection electrode 152 and the second connection electrode 151 can be disposed on the same layer and made of the same material. Therefore, the first connection electrode 152 and the second connection electrode 151 can be formed by the same process. However, the present disclosure is not limited thereto.

The first connection electrode 152 can be disposed on the first planarization layer 114 and electrically connected to the transistor TR. The first connection electrode 152 can be connected to the drain electrode DE of the transistor TR. Specifically, the first connection electrode 152 can be electrically connected to the drain electrode DE of the first transistor TR through contact holes formed in the insulation layer 113 and the first planarization layer 114.

The second connection electrode 151 can be connected to the power line VL. Specifically, the second connection electrode 151 can be electrically connected to the power line VL through the contact holes formed in the insulation layer 113 and the first planarization layer 114.

The first connection electrode 152 and the second connection electrode 151 can each be made of any one of various metallic materials having conductivity, for example, tantalum (Ta), molybdenum (Mo), aluminum (Al), chromium (Cr), gold (Au), titanium (Ti), nickel (Ni), neodymium (Nd), copper (Cu), and an alloy of two or more of these materials or configured as a multilayer made of any one of these materials. However, the present disclosure is not limited thereto. In addition, the first connection electrode 152 and the second connection electrode 151 can be made of the same material and formed simultaneously.

The second planarization layer 115 can be disposed on the first connection electrode 152 and the second connection electrode 151. The second planarization layer 115 can be disposed on the first planarization layer 114 and the first connection electrode 152 and surround the light-emitting element LED.

For example, the second planarization layer 115 can be disposed to expose a part of the first connection electrode 152 and the second connection electrode 151. Therefore, the second planarization layer 115 can provide a groove in which the light-emitting element LED is disposed to be electrically connected to the electrodes of the display device 100. Meanwhile, FIG. 3B illustrates that the second planarization layer 115 and a part of the side surface of the light-emitting element LED are in contact with each other. However, the second planarization layer 115 and the light-emitting element LED can be disposed to be spaced apart from each other to make it easy to repair a defect. The present disclosure is not limited thereto.

The second planarization layer 115 can be an organic insulation layer. For example, the first planarization layer 114 can be made of any one of photo acrylic resin, acrylic resin, epoxy resin, phenolic resin, polyamide-based resin, polyimide-based resin, unsaturated polyester-based resin, polyphenylene-based resin, polyphenylene sulfide-based resin, benzocyclobutene, and photoresist. However, the present disclosure is not limited thereto. The first planarization layer 114 can be configured as a multilayer structure such as an inorganic layer/organic layer structure, an inorganic layer/organic layer/inorganic layer structure, or the like.

The light-emitting element LED can be disposed on the first connection electrode 152 and a part of the second connection electrode 151 exposed from the second planarization layer 115. The light-emitting element LED can be disposed on the first connection electrode 152 and the second connection electrode 151 and electrically connected to the first connection electrode 152 and the second connection electrode 151. For example, the n-type electrode NE of the light-emitting element LED can be electrically connected to the second connection electrode 151, and the p-type layer PL of the light-emitting element LED can be electrically connected to the first connection electrode 152. Therefore, the light-emitting element LED can be electrically connected to the transistor TR and the power line VL.

Meanwhile, the light-emitting element LED can be disposed on the first connection electrode 152 and the second connection electrode 151 and electrically connected to the first connection electrode 152 and the second connection electrode 151. Therefore, the light-emitting element LED can be electrically connected to the first connection electrode 152 and the second connection electrode 151 only by physical contact with the first connection electrode 152 and the second connection electrode 151.

The light-emitting element LED can include the p-type layer PL, the active layer EL, the n-type layer NL, the n-type electrode NE, and the passivation layer PAS. The light-emitting element LED can be electrically connected to the transistor TR and the power line VL and configured to emit light.

The bank 116 can be disposed on the second planarization layer 115. The bank 116 can be disposed to define light-emitting areas of the plurality of subpixels. For example, the bank 116 can be made of an opaque material including a black material, for example, black resin to reduce a color mixture between the plurality of subpixels. However, the present disclosure is not limited thereto.

For example, the light-emitting element and the display panel need to be electrically connected to inspect a defective pixel. In this case, a process of electrically connecting the light-emitting element and the display panel is performed by transferring the light-emitting element on the display panel and then forming lines and the like on the light-emitting element so that the lines and the like are connected to the electrodes. In addition, an organic layer can be further disposed above the light-emitting element to stably couple the light-emitting element and the display panel. Therefore, in case that a repair process is required to replace a light-emitting element having a defective pixel, the components, such as the lines disposed above the light-emitting element, can also be damaged. For this reason, the above-mentioned repair process cannot be easily performed.

In addition, even though the light-emitting element is configured as a horizontal type (lateral type) so as to be electrically connected to the display panel disposed below the light-emitting element to make it easy to repair a defective pixel, the light-emitting area is narrow in comparison with a size of the light-emitting element, which causes an additional problem disadvantageous in implementing the high-resolution display device.

In the display device 100 according to the embodiment of the present disclosure, the first connection electrode 152 and the second connection electrode 151 can be disposed below the light-emitting element LED and electrically connected to the light-emitting element LED, and the light-emitting element LED can be configured to be electrically connected to the first connection electrode 152 and the second connection electrode 151 only by physical contact, which can make it easy to repair a defect.

For example, the lower end of the n-type electrode NE and the lower end of the p-type layer PL are disposed on the same plane in the display device 100 according to the embodiment of the present disclosure, the first and second connection electrodes of the display device can be disposed below the light-emitting element LED and electrically connected to the light-emitting element LED. Here, it is possible to repair a defective pixel without damaging the components disposed above the light-emitting element LED. In addition, in the display device 100 according to the embodiment of the present disclosure, the n-type electrode NE is disposed to have the structure that caps the outer surface of the light-emitting element LED. Therefore, the light-emitting element LED can be electrically connected to the first connection electrode 152 and the second connection electrode 151 only by physical contact without a separate component such as a line to be electrically connected to the first connection electrode 152 and the second connection electrode 151.

As such, the process of removing the light-emitting element LED from the first connection electrode 152 and the second connection electrode 151 to repair a defective pixel can be performed by performing a process of physically separating the light-emitting element LED from the first connection electrode 152 and the second connection electrode 151. Further, the process of removing the light-emitting element LED from the first connection electrode 152 and the second connection electrode 151 can be facilitated, which can make it easier to repair a defective pixel. Therefore, in the display device 100 according to the embodiment of the present disclosure, the first connection electrode 152 and the second connection electrode 151 can be disposed below the light-emitting element LED and electrically connected to the light-emitting element LED, and the light-emitting element LED can be configured to be electrically connected to the first connection electrode 152 and the second connection electrode 151 only by physical contact, which can make it easy to repair a defect.

In addition, in the display device 100 according to the embodiment of the present disclosure, the n-type electrode NE is disposed to have the structure that caps the outer surface of the light-emitting element LED, which can implement the high-resolution display device 100.

Specifically, in the display device 100 according to the embodiment of the present disclosure, the n-type electrode NE is disposed on the outermost layer disposed on the side surface of the light-emitting element LED and the upper surface of the light-emitting element LED, such that the n-type electrode NE can be disposed to have the structure that caps the outer surface of the light-emitting element LED. Here, the light-emitting element LED can be configured to be electrically connected to the first connection electrode 152 and the second connection electrode 151 disposed below the light-emitting element LED, and at the same time, the light-emitting element LED can be configured as a vertical type light-emitting element capable of implementing high resolution in comparison with a horizontal type light-emitting element. Therefore, in the display device 100 according to the embodiment of the present disclosure, the n-type electrode NE is disposed to have the structure that caps the outer surface of the light-emitting element LED, which can implement the high-resolution display device 100.

Meanwhile, an inorganic insulation layer can be further disposed on the light-emitting element. For example, after a defect of the light-emitting element is identified, the inorganic insulation layer can be disposed on the light-emitting element to protect the light-emitting element from the outside. For example, the inorganic insulation layer can be configured as a single layer made of silicon nitride (SiNx) or silicon oxide (SiOx) that is an inorganic material. Alternatively, the inorganic insulation layer can be configured as a multilayer made of silicon nitride (SiNx) or silicon oxide (SiOx). However, the present disclosure is not limited thereto.

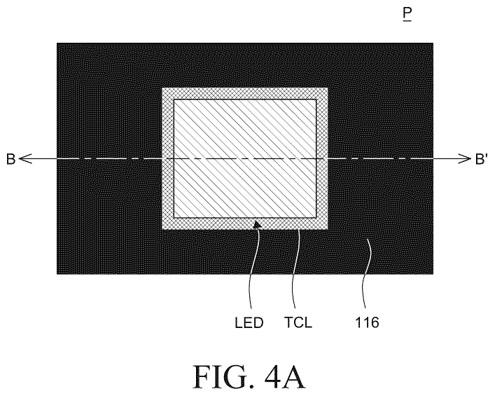

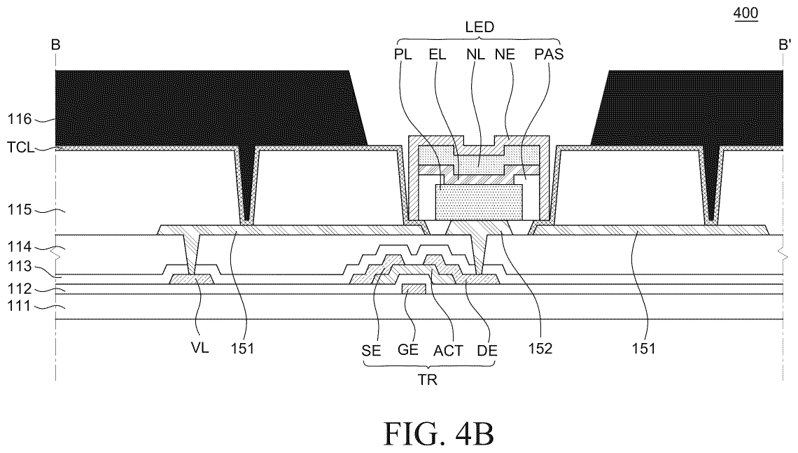

Hereinafter, a display device 400 according to another embodiment of the present disclosure will be described in detail with reference to FIGS. 4A and 4B. Each pixel of the display device 400 can have the configuration shown in FIGS. 4A and 4B.

FIG. 4A is a schematic enlarged top plan view of one pixel of the display device according to another embodiment of the present disclosure.

FIG. 4B is a cross-sectional view taken along line B-B′ in FIG. 4A.

The display device 400 in FIGS. 4A and 4B is substantially identical in configuration to the display device 100 in FIGS. 1 to 3B, except that a conductive layer TCL is further disposed. Therefore, repeated descriptions of the identical components will be omitted or may be briefly provided.

With reference to FIGS. 4A and 4B, the conductive layer TCL can be disposed on the first connection electrode 152 and the second planarization layer 115. The conductive layer TCL can extend to an upper surface of a part of the first connection electrode 152 exposed from the second planarization layer 115, and the conductive layer TCL can be electrically connected to the first connection electrode 152.

In addition, the conductive layer TCL can be disposed to contact the first connection electrode 152 through a contact hole formed in the second planarization layer 115, and the conductive layer TCL can be further electrically connected to the first connection electrode 152.

Meanwhile, with reference to FIG. 4B, the conductive layer TCL can be disposed to contact a part of the side surface of the light-emitting element LED by an inclined shape of the side surface of the second planarization layer 115 disposed to surround the light-emitting element LED. Therefore, the conductive layer TCL can be disposed below the light-emitting element LED and disposed on the side surface of the light-emitting element LED so as to contact the light-emitting element LED.

For example, the conductive layer TCL can be made of a transparent conducting oxide such as indium tin oxide (ITO) or indium zinc oxide (IZO). However, the present disclosure is not limited thereto.

In the display device 400 according to another embodiment of the present disclosure, the conductive layer TCL is disposed on the first connection electrode 152 and the second planarization layer 115, which can improve reliability of the display device.

For example, in the display device 400 according to another embodiment of the present disclosure, the conductive layer TCL disposed on the second planarization layer 115 and the first connection electrode 152 can be disposed to contact a part of the side surface of the light-emitting element LED. Further, the conductive layer TCL can be disposed below the light-emitting element LED and disposed on the side surface of the light-emitting element LED so as to contact the light-emitting element LED. In addition, the light-emitting element LED can be more stably and electrically connected to the conductive layer TCL. In addition, with the above-mentioned arrangement structure of the light-emitting element LED and the conductive layer TCL, the light-emitting element LED can be more stably and physically connected to the conductive layer. Therefore, in the display device 400 according to another embodiment of the present disclosure, the conductive layer TCL is disposed on the first connection electrode 152 and the second planarization layer 115, which can improve reliability of the display device.

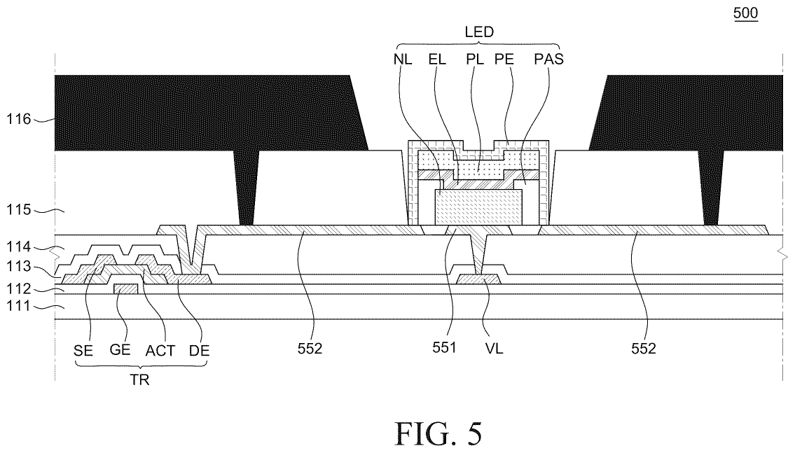

Hereinafter, a display device 500 according to still another embodiment of the present disclosure will be described in detail with reference to FIG. 5.

FIG. 5 is a cross-sectional view of the display device according to still another embodiment of the present disclosure.

The display device 500 in FIG. 5 is substantially identical in configuration to the display device 100 in FIGS. 1 to 3B, except for the order in which the constituent elements of the light-emitting element LED are stacked and positions of first and second connection electrodes 551 and 552. Therefore, repeated descriptions of the identical components will be omitted or may be provided briefly.

With reference to FIG. 5, the light-emitting element LED of the display device 500 according to still another embodiment of the present disclosure can include the n-type layer NL, the active layer EL, the p-type layer PL, a p-type electrode PE, and the passivation layer PAS.

The n-type layer NL is a layer for supplying electrons to the active layer EL. For example, the n-type layer NL can be formed by doping a gallium nitride (GaN) semiconductor layer, which is formed by growing a gallium nitride (GaN) layer, with n-type impurities such as silicon (Si). However, the present disclosure is not limited thereto. The n-type layer NL can be a first type semiconductor layer.

The passivation layer PAS can be disposed on the n-type layer NL.

The passivation layer PAS can be disposed to cover a side surface of the n-type layer NL and an edge of an upper surface of the n-type layer NL extending from the side surface of the n-type layer NL.

The passivation layer PAS can be disposed to expose a part of the upper surface of the n-type layer NL.

The passivation layer PAS can be made of an insulating material. For example, the passivation layer PAS can be configured as an inorganic layer made of silicon nitride (SiNx), silicon oxide (SiOx), and silicon oxynitride (SiON). However, the present disclosure is not limited thereto.

The active layer EL can be disposed on the n-type layer NL and the passivation layer PAS. For example, the active layer EL can be disposed to contact the passivation layer PAS and a part of the upper surface of the n-type layer NL exposed from the passivation layer PAS. Therefore, the active layer EL can be electrically connected to the n-type layer NL.

The active layer EL is a layer that emits light by combining electrons and positive holes. For example, the active layer EL can be a multi-quantum well structure in which a plurality of barrier layers and a plurality of well layers are alternately disposed, the well layer is configured as an indium gallium nitride (InGaN) layer, and the barrier layer is made of gallium nitride (GaN). However, the present disclosure is not limited thereto.

The p-type layer PL can be disposed on the active layer EL. The p-type layer PL is a layer for injecting positive holes into the active layer EL. For example, the p-type layer PL can be formed by doping a gallium nitride (GaN) semiconductor layer, which is formed by growing a gallium nitride (GaN) layer, with p-type impurities such as magnesium (Mg), zinc (Zn), and beryllium (Be). However, the present disclosure is not limited thereto. The p-type layer PL can be a second type semiconductor layer.

A p-type electrode PE can be disposed on the p-type layer PL. The p-type electrode PE can be disposed on an outermost layer disposed on the side surface of the light-emitting element LED and the upper surface of the light-emitting element LED. For example, the p-type electrode PE can be disposed to cover the side surface of the passivation layer PAS, the side surface of the active layer EL, the side surface of the p-type layer PL, and the upper surface of the n-type layer PL. For example, the p-type electrode PE can be disposed to have a structure that caps the outer surface of the light-emitting element LED.

The p-type electrode PE is a layer disposed to inject positive holes into the active layer EL through the p-type layer PL. The p-type electrode PE can be made of an electrically conductive material having transparency so that the p-type electrode PE can transmit light upward, which is emitted from the active layer EL. For example, the p-type electrode PE can be a transparent electrode. For example, the p-type electrode PE can be made of transparent conducting oxide or made of indium tin oxide (ITO) or indium zinc oxide (IZO). However, the present disclosure is not limited thereto.

Meanwhile, in the light-emitting element LED of the display device 500 according to still another embodiment of the present disclosure, the lower end of the p-type electrode PE and the lower end of the n-type layer NL are disposed on the same plane, such that the first connection electrode 552 and the second connection electrode 551 of the display device 500 can be disposed below the light-emitting element LED and electrically connected to the light-emitting element LED. Therefore, the lower portion of the light-emitting element LED can be electrically connected to the electrodes of the display device 500, and at the same time, the light-emitting element LED can constitute a vertical type light-emitting element.

With reference to FIG. 5, in the display device 500 according to still another embodiment of the present disclosure, the first connection electrode 552 and the second connection electrode 551 can be disposed on the first planarization layer 114.

For example, the first connection electrode 552 and the second connection electrode 551 can be disposed on the same layer and made of the same material. Therefore, the first connection electrode 552 and the second connection electrode 551 can be formed by the same process. However, the present disclosure is not limited thereto.

The first connection electrode 552 can be disposed on the first planarization layer 114 and electrically connected to the transistor TR. The first connection electrode 552 can be connected to the drain electrode DE of the transistor TR. Specifically, the first connection electrode 552 can be electrically connected to the drain electrode DE of the first transistor TR through contact holes formed in the insulation layer 113 and the first planarization layer 114. However, the present disclosure is not limited thereto. The first connection electrode 552 can be connected to the source electrode SE of the transistor TR.

In addition, the second connection electrode 551 can be connected to the power line VL. For example, the second connection electrode 551 can be electrically connected to the power line VL through the contact holes formed in the insulation layer 113 and the first planarization layer 114.

The first connection electrode 552 and the second connection electrode 551 can each be made of any one of various metallic materials having conductivity, for example, tantalum (Ta), molybdenum (Mo), aluminum (Al), chromium (Cr), gold (Au), titanium (Ti), nickel (Ni), neodymium (Nd), copper (Cu), and an alloy of two or more of these materials or configured as a multilayer made of any one of these materials. However, the present disclosure is not limited thereto. In addition, the first connection electrode 552 and the second connection electrode 551 can be made of the same material and formed simultaneously.

The second planarization layer 115 can be disposed on the first connection electrode 552 and the second connection electrode 551. The second planarization layer 115 can be disposed on the first planarization layer 114 and the second connection electrode 551 and surround the light-emitting element LED.

For example, the second planarization layer 115 can be disposed to expose a part of the first connection electrode 552 and the second connection electrode 551. Therefore, the second planarization layer 115 can provide a groove in which the light-emitting element LED is disposed to be electrically connected to the electrodes of the display device 500. Meanwhile, FIG. 5 illustrates that the second planarization layer 115 and a part of the side surface of the light-emitting element LED are in contact with each other. However, the second planarization layer 115 and the light-emitting element LED can be disposed to be spaced apart from each other to make it easy to repair a defect. The present disclosure is not limited thereto.

The second planarization layer 115 can be an organic insulation layer. For example, the first planarization layer 114 can be made of any one of photo acrylic resin, acrylic resin, epoxy resin, phenolic resin, polyamide-based resin, polyimide-based resin, unsaturated polyester-based resin, polyphenylene-based resin, polyphenylene sulfide-based resin, benzocyclobutene, and photoresist. However, the present disclosure is not limited thereto. The first planarization layer 114 can be configured as a multilayer structure such as an inorganic layer/organic layer structure, an inorganic layer/organic layer/inorganic layer structure, or the like.

The light-emitting element LED can be disposed on the second connection electrode 551 and a part of the first connection electrode 552 exposed from the second planarization layer 115. The light-emitting element LED can be disposed on the first connection electrode 552 and the second connection electrode 551 and electrically connected to the first connection electrode 552 and the second connection electrode 551. For example, the p-type electrode PE of the light-emitting element LED can be electrically connected to the first connection electrode 552, and the n-type layer NL of the light-emitting element LED can be electrically connected to the second connection electrode 551. Therefore, the light-emitting element LED can be electrically connected to the transistor TR and the power line VL.

Meanwhile, the light-emitting element LED can be disposed on the first connection electrode 552 and the second connection electrode 551 and electrically connected to the first connection electrode 552 and the second connection electrode 551. Therefore, the light-emitting element LED can be electrically connected to the first connection electrode 552 and the second connection electrode 551 only by physical contact with the first connection electrode 552 and the second connection electrode 551.

In the display device 500 according to still another embodiment of the present disclosure, the first connection electrode 552 and the second connection electrode 551 can be disposed below the light-emitting element LED and electrically connected to the light-emitting element LED, and the light-emitting element LED can be configured to be electrically connected to the first connection electrode 152 and the second connection electrode 151 only by physical contact, which can make it easy to repair a defect.

For example, in the display device 500 according to still another embodiment of the present disclosure, the lower end of the p-type electrode PE and the lower end of the n-type layer NL are disposed on the same plane, such that the first connection electrode 552 and the second connection electrode 551 of the display device 500 can be disposed below the light-emitting element LED and electrically connected to the light-emitting element LED. Therefore, it is possible to repair a defective pixel without damaging the components disposed above the light-emitting element LED. In addition, in the display device 500 according to still another embodiment of the present disclosure, the p-type electrode PE is disposed to have the structure that caps the outer surface of the light-emitting element LED.

As such, the light-emitting element LED can be electrically connected to the first connection electrode 552 and the second connection electrode 551 only by physical contact without a separate component such as a line to be electrically connected to the first connection electrode 152 and the second connection electrode 151. Thus, the process of removing the light-emitting element LED from the first connection electrode 552 and the second connection electrode 551 to repair a defective pixel can be performed by performing the process of physically separating the light-emitting element LED from the first connection electrode 552 and the second connection electrode 551. Further, the process of removing the light-emitting element LED from the first connection electrode 552 and the second connection electrode 551 can be facilitated, which can make it easier to repair a defective pixel. Accordingly, in the display device 500 according to still another embodiment of the present disclosure, the first connection electrode 552 and the second connection electrode 551 can be disposed below the light-emitting element LED and electrically connected to the light-emitting element LED, and the light-emitting element LED can be configured to be electrically connected to the first connection electrode 152 and the second connection electrode 151 only by physical contact, which can make it easy to repair a defect.

In addition, in the display device 500 according to still another embodiment of the present disclosure, the p-type electrode PE is disposed to have the structure that caps the outer surface of the light-emitting element LED, which can implement the high-resolution display device 500.

Specifically, in the display device 500 according to still another embodiment of the present disclosure, the p-type electrode PE is disposed on the outermost layer disposed on the side surface of the light-emitting element LED and the upper surface of the light-emitting element LED, such that the p-type electrode PE can be disposed to have the structure that caps the outer surface of the light-emitting element LED. The light-emitting element LED can be configured to be electrically connected to the first connection electrode 552 and the second connection electrode 551 disposed below the light-emitting element LED, and at the same time, the light-emitting element LED can be configured as the vertical type light-emitting element capable of implementing high resolution in comparison with the horizontal type light-emitting element. Therefore, in the display device 500 according to still another embodiment of the present disclosure, the p-type electrode PE is disposed to have the structure that caps the outer surface of the light-emitting element LED, which can implement the high-resolution display device 500.

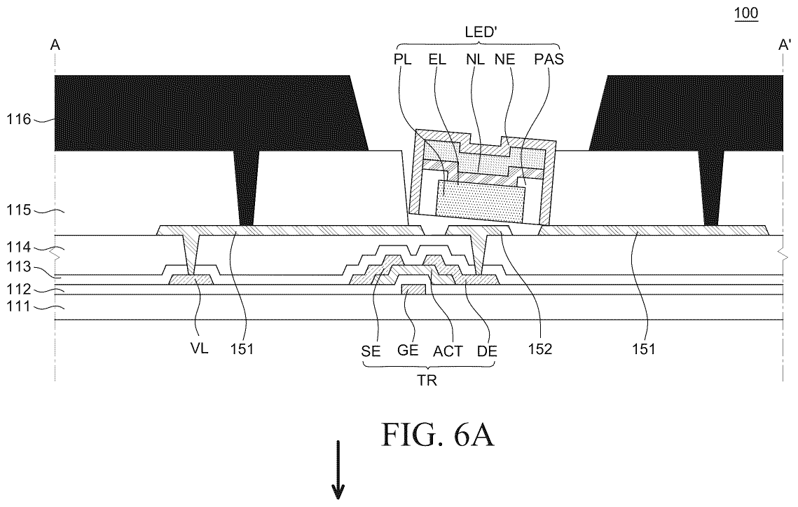

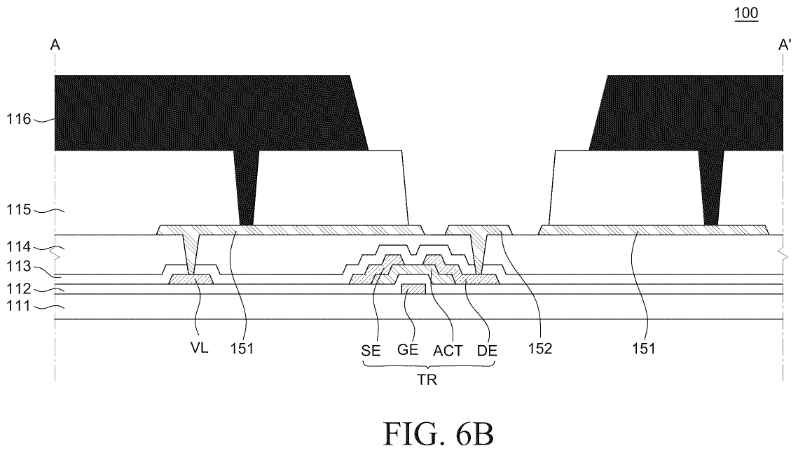

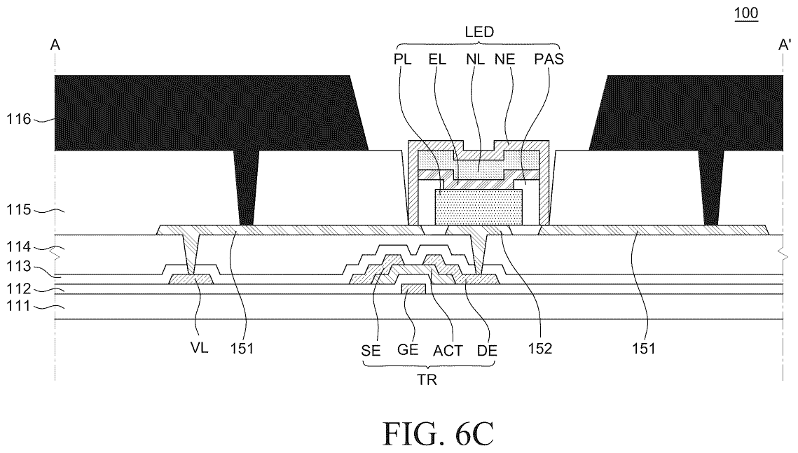

Hereinafter, a process of repairing a defective pixel of the display device according to the embodiment of the present disclosure will be described in detail with reference to FIGS. 6A to 6C.

FIGS. 6A to 6C are structure diagrams for illustrating a process of repairing a defective pixel of the display device according to the embodiment of the present disclosure.

For convenience of description, FIGS. 6A to 6C exemplarily illustrate a pixel P on which a single light-emitting element LED is disposed.

First, with reference to FIG. 6A, a process of disposing the light-emitting element LED′ on the first connection electrode 152 and the second connection electrode 151 and identifying a defective pixel by inspecting the plurality of pixels P of the display device 100 is performed. In this case, for example, the identification of the defective pixel can be performed by an illumination check or the like. Meanwhile, FIG. 6A exemplarily illustrates a defect in which a light-emitting element LED′ is misaligned with a defective pixel. However, the light-emitting element LED′ can be defective. The present disclosure is not limited thereto.

Next, with reference to FIG. 6B, a process of removing the light-emitting element LED′ having a pixel, which has been identified as having a defect, is performed to repair the defective pixel. For example, a process of removing the light-emitting element LED′ having the defective pixel can be performed by physically separating the defective light-emitting element LED′ from the first connection electrode 152 and the second connection electrode 151.

Lastly, with reference to FIG. 6C, the process of repairing the defective pixel can be completed by disposing again a normal light-emitting element LED on the first connection electrode 152 and the second connection electrode 151 from which the defective light-emitting element LED′ has been removed.

The exemplary embodiments of the present disclosure can also be described as follows:

According to an aspect of the present disclosure, there is provided a light-emitting element. The light-emitting element includes a first type semiconductor layer, a passivation layer disposed to cover a side surface and an edge of an upper surface of the first type semiconductor layer, an active layer above the first type semiconductor layer and the passivation layer, a second type semiconductor layer above the active layer and an electrode disposed to cover a side surface of the passivation layer, a side surface of the active layer, a side surface of the second type semiconductor layer, and an upper surface of the second type semiconductor layer.

The passivation layer can be disposed to expose a part of the upper surface of the first type semiconductor layer, and the active layer can contact the exposed part of the upper surface of the first type semiconductor layer.

The electrode can be a transparent electrode. The electrode can be disposed on an outermost layer disposed on a side surface and an upper surface of the light-emitting element.

A lower end of the electrode and a lower end of the first type semiconductor layer can be disposed on the same plane.

The passivation layer can be disposed between the electrode and the first type semiconductor layer.

The first type semiconductor layer can be a semiconductor layer doped with p-type impurities, the second type semiconductor layer can be a semiconductor layer doped with n-type impurities, and the electrode can be an n-type electrode.

The first type semiconductor layer can be a semiconductor layer doped with n-type impurities, the second type semiconductor layer can be a semiconductor layer doped with p-type impurities, and the electrode can be a p-type electrode.

According to an aspect of the present disclosure, there is provided a display device. The display device includes a substrate on which a plurality of pixels comprising a plurality of subpixels is defined, a plurality of transistors respectively disposed on the plurality of subpixels, a first planarization layer disposed above the plurality of transistors, a first connection electrode disposed above the first planarization layer and connected to the plurality of transistors, a second connection electrode disposed above the first planarization layer and spaced apart from the first connection electrode and a light-emitting element disposed above the first connection electrode and the second connection electrode and electrically connected to the first connection electrode and the second connection electrode, the light-emitting element includes a first type semiconductor layer, a passivation layer disposed to cover a side surface and an edge of an upper surface of the first type semiconductor layer, an active layer disposed above the first type semiconductor layer and the passivation layer, a second type semiconductor layer disposed above the active layer, and an electrode disposed to cover a side surface of the passivation layer, a side surface of the active layer, a side surface of the second type semiconductor layer, and an upper surface of the second type semiconductor layer.

The first type semiconductor layer can be a semiconductor layer doped with p-type impurities, the second type semiconductor layer can be a semiconductor layer doped with n-type impurities, and the electrode can be an n-type electrode.

The electrode of the light-emitting element can be electrically connected to the second connection electrode, and the first type semiconductor layer of the light-emitting element can be electrically connected to the first connection electrode.

The first type semiconductor layer can be a semiconductor layer doped with n-type impurities, the second type semiconductor layer can be a semiconductor layer doped with p-type impurities, and the electrode can be a p-type electrode.

The electrode of the light-emitting element can be electrically connected to the first connection electrode, and the first type semiconductor layer of the light-emitting element can be electrically connected to the second connection electrode.

The display device can further comprise a second planarization layer disposed above the first planarization layer and the second connection electrode and configured to surround the light-emitting element.

The second planarization layer can be disposed to expose a part of the second connection electrode and the first connection electrode, and the light-emitting element can be disposed above the exposed part of the second connection electrode and the exposed first connection electrode.

The display device can further comprise a bank disposed above the second planarization layer, the bank can include a black material.

The display device can further comprise a conductive layer disposed above the second connection electrode and the second planarization layer, the light-emitting element can be electrically connected to the second connection electrode by the conductive layer.

The conductive layer can contact a part of a side surface of the light-emitting element.

The conductive layer can contact the second connection electrode through a contact hole formed in the second planarization layer.

The conductive layer can be made of a transparent conducting oxide.

Although the exemplary embodiments of the present disclosure have been described in detail with reference to the accompanying drawings, the present disclosure is not limited thereto and can be embodied in many different forms without departing from the technical concept of the present disclosure. Thus, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A light-emitting device comprising:
a first type semiconductor layer;
a passivation layer disposed to cover a side surface of the first type semiconductor layer and an edge of an upper surface of the first type semiconductor layer;
an active layer disposed above the first type semiconductor layer and the passivation layer;
a second type semiconductor layer disposed above the active layer; and
an electrode disposed to cover a side surface of the passivation layer, a side surface of the active layer, a side surface of the second type semiconductor layer, and an upper surface of the second type semiconductor layer.

2. The light-emitting device of claim 1, wherein the passivation layer is disposed to expose a part of the upper surface of the first type semiconductor layer, and the active layer contacts the exposed part of the upper surface of the first type semiconductor layer.

3. The light-emitting device of claim 1, wherein the electrode is a transparent electrode.

4. The light-emitting device of claim 1, wherein the electrode is disposed above an outermost layer disposed above a side surface and an upper surface of the light-emitting device.

5. The light-emitting device of claim 1, wherein a lower end of the electrode and a lower end of the first type semiconductor layer are disposed above a same plane.

6. The light-emitting device of claim 5, wherein the passivation layer is disposed between the electrode and the first type semiconductor layer.

7. The light-emitting device of claim 1, wherein the first type semiconductor layer is a semiconductor layer doped with p-type impurities, the second type semiconductor layer is a semiconductor layer doped with n-type impurities, and the electrode is an n-type electrode.

8. The light-emitting device of claim 1, wherein the first type semiconductor layer is a semiconductor layer doped with n-type impurities, the second type semiconductor layer is a semiconductor layer doped with p-type impurities, and the electrode is a p-type electrode.

9. A display device comprising:
a substrate above which a plurality of pixels each comprising a plurality of subpixels are disposed;
a plurality of transistors respectively disposed above the plurality of subpixels;
a first planarization layer disposed above the plurality of transistors;
a first connection electrode disposed above the first planarization layer and connected to the plurality of transistors;
a second connection electrode disposed above the first planarization layer and spaced apart from the first connection electrode; and
a light-emitting element disposed above the first connection electrode and the second connection electrode, and electrically connected to the first connection electrode and the second connection electrode,
wherein the light-emitting element includes:
a first type semiconductor layer,
a passivation layer disposed to cover a side surface of the first type semiconductor layer and an edge of an upper surface of the first type semiconductor layer,
an active layer disposed above the first type semiconductor layer and the passivation layer,
a second type semiconductor layer disposed above the active layer, and
an electrode disposed to cover a side surface of the passivation layer, a side surface of the active layer, a side surface of the second type semiconductor layer, and an upper surface of the second type semiconductor layer.

10. The display device of claim 9, wherein the first type semiconductor layer is a semiconductor layer doped with p-type impurities, the second type semiconductor layer is a semiconductor layer doped with n-type impurities, and the electrode is an n-type electrode.

11. The display device of claim 10, wherein the electrode of the light-emitting element is electrically connected to the second connection electrode, and the first type semiconductor layer of the light-emitting element is electrically connected to the first connection electrode.

12. The display device of claim 9, wherein the first type semiconductor layer is a semiconductor layer doped with n-type impurities, the second type semiconductor layer is a semiconductor layer doped with p-type impurities, and the electrode is a p-type electrode.

13. The display device of claim 12, wherein the electrode of the light-emitting element is electrically connected to the first connection electrode, and the first type semiconductor layer of the light-emitting element is electrically connected to the second connection electrode.

14. The display device of claim 9, further comprising:
a second planarization layer disposed above the first planarization layer and the second connection electrode and configured to surround the light-emitting element.

15. The display device of claim 14, wherein the second planarization layer is disposed to expose a part of the second connection electrode and the first connection electrode, and the light-emitting element is disposed above the exposed part of the second connection electrode and the exposed first connection electrode.

16. The display device of claim 14, further comprising:
a bank disposed above the second planarization layer,
wherein the bank includes a black material.

17. The display device of claim 14, further comprising:
a conductive layer disposed above the second connection electrode and the second planarization layer,
wherein the light-emitting element is electrically connected to the second connection electrode by the conductive layer.

18. The display device of claim 17, wherein the conductive layer contacts a part of a side surface of the light-emitting element.

19. The display device of claim 17, wherein the conductive layer contacts the second connection electrode through a contact hole formed in the second planarization layer.

20. The display device of claim 17, wherein the conductive layer includes transparent conducting oxide.
